(19) United States
(12) Patent Application Publication
(10) Pub. No.: US 2019/0115725 A1
(43) Pub. Date: Apr. 18, 2019

(54) VERTICAL CAVITY SURFACE EMITTING LASER AND METHOD FOR FABRICATING THE SAME

(71) Applicant: HLJ TECHNOLOGY CO., LTD., HSINCHU COUNTY (TW)

(72) Inventors: LI-HUNG LAI, HSINCHU COUNTY (TW); LI-WEN LAI, HSINCHU COUNTY (TW); CHIH-HUNG CHUANG, HSINCHU COUNTY (TW); MIN-LUN WU, HSINCHU COUNTY (TW)

(21) Appl. No.: 16/161,541

(22) Filed: Oct. 16, 2018

(30) Foreign Application Priority Data
Oct. 18, 2017 (TW) 106135716

(51) Int. Cl. H01S 5/183

(52) U.S. Cl. CPC H01S 5/18361; H01S 5/18397; H01S 5/18344

(57) ABSTRACT

A vertical cavity surface emitting laser (VCSEL) and a method for fabricating the same are provided. The VCSEL includes an epitaxial laminate, a lower electrode layer, an upper electrode layer and a current spreading layer. The epitaxial laminate at least includes a first reflector, a second reflector, and an active layer disposed therebetween for generating an initial laser beam. The upper and lower electrode layers jointly define a current path passing through the active layer, and the upper electrode layer has an aperture for defining a light-emitting region. The current spreading layer disposed on the second reflector and electrically connected to the upper electrode layer includes a plurality of beam splitting structures positioned at a light emergent side thereof, and the beam splitting structures is located in the aperture so that the initial laser beam is divided into a plurality of sub-beams.

### CROSS-REFERENCE TO RELATED PATENT APPLICATION

This application claims the benefit of priority to Taiwan Patent Application No. 106135716, filed on Oct. 18, 2017. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a vertical cavity surface emitting laser and a method for fabricating the same, and more particularly to a vertical cavity surface emitting laser providing a more uniform current injection and method for fabricating the same.

### BACKGROUND OF THE DISCLOSURE

A conventional laser module having a two-dimensional vertical cavity surface emitting laser (VCSEL) array can be applied in an optical sensing apparatus for sensing a three-dimensional contour of an object. In general, the larger the number of the VCSELs applied in the laser module, the higher the 3D contour resolution that can be sensed by the optical sensing apparatus will be.

However, using a large number of the VCSELs in the optical sensing apparatus may entail larger size of the optical sensing apparatus. Furthermore, the fabrication costs and layout complexity of the optical sensing apparatus having a large number of the VCSELs may be increased.

### SUMMARY OF THE DISCLOSURE

In response to the above-referenced technical inadequacies, the present disclosure provides a vertical cavity surface emitting laser (VCSEL) and a method for fabricating the same so as to improve the resolution of the optical sensing apparatus without increasing the number of the VCSELs.

In one aspect, the present disclosure provides a vertical cavity surface emitting laser. The vertical cavity surface emitting laser includes an epitaxial laminate, a lower electrode layer, an upper electrode layer, and a current spreading layer. The epitaxial laminate includes a first reflector, an active layer, and a second reflector. The first reflector, the active layer and the second reflector are disposed on the substrate, and the active layer is interposed between the first and second reflectors to generate an initial laser beam. The lower electrode layer is disposed on the epitaxial laminate. The upper electrode layer is disposed on the second reflector, in which the upper electrode layer and the lower electrode layer jointly define a current path therebetween passing through the active layer, and the upper electrode layer has an aperture for defining a light-emitting region. The current spreading layer is disposed on the second reflector and electrically connected to the lower electrode layer. The current spreading layer includes a plurality of light-splitting structures located at a light emergent side of the current spreading layer, and the light-splitting structures are located in the aperture so that the initial laser beam passing through the light-splitting structures is divided into a plurality of sub beams.

Therefore, one of the advantages of the present disclosure is that in the vertical cavity surface emitting laser and the method for fabricating the same, by “disposing the current spreading layer having a plurality of light splitting structures on the second reflector,” an initial laser beam generated at the active layer can be divided into a plurality of sub beams which emit out of the vertical cavity surface emitting laser through the light splitting structures.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the detailed description and the accompanying drawings, in which:

FIG. 1A is a schematic cross-sectional view of a vertical cavity surface emitting laser (VCSEL) according to an embodiment of the present disclosure.

FIG. 1B is a schematic top view of the current spreading layer located in the aperture of the upper electrode layer shown in FIG. 1A according to an embodiment of the present disclosure.

FIG. 2 is a schematic top view of the current spreading layer located in the aperture of the upper electrode layer according to another embodiment of the present disclosure.

FIG. 3 is a schematic sectional view of a vertical cavity surface emitting laser according to another embodiment of the present disclosure.

FIG. 4 is a schematic top view of the current spreading layer located in the aperture of the upper electrode layer according to another embodiment of the present disclosure.

FIG. 5A is a schematic exploded view of a VCSEL according to yet another embodiment of the present disclosure.

FIG. 5B is a schematic sectional view of the VCSEL shown in FIG. 5A.

FIG. 6 is a flowchart of a method for fabricating a VCSEL according to an embodiment of the present disclosure.

FIG. 7A is a schematic sectional view of a VCSEL in one of the steps shown in FIG. 6 according to an embodiment of the present disclosure.

FIG. 7B is a schematic sectional view of a VCSEL in one of the steps shown in FIG. 6 according to an embodiment of the present disclosure.

FIG. 7C is a schematic sectional view of a VCSEL in one of the steps shown in FIG. 6 according to an embodiment of the present disclosure.

FIG. 7D is a schematic sectional view of a VCSEL in one of the steps shown in FIG. 6 according to an embodiment of the present disclosure.

FIG. 7E is a schematic sectional view of a VCSEL in one of the steps shown in FIG. 6 according to an embodiment of the present disclosure.

FIG. 7F is a schematic sectional view of a VCSEL in one of the steps shown in FIG. 6 according to an embodiment of the present disclosure.

FIG. 7G is a schematic sectional view of a VCSEL in one of the steps shown in FIG. 6 according to an embodiment of the present disclosure.

FIG. 7H is a schematic sectional view of a VCSEL in one of the steps shown in FIG. 6 according to an embodiment of the present disclosure.

FIG. 7I is a schematic sectional view of a VCSEL in one of the steps shown in FIG. 6 according to an embodiment of the present disclosure.

FIG. 7J is a schematic sectional view of a VCSEL in one of the steps shown in FIG. 6 according to an embodiment of the present disclosure.

FIG. 7K is a schematic sectional view of a VCSEL in one of the steps shown in FIG. 6 according to an embodiment of the present disclosure.

FIG. 7L is a schematic sectional view of a VCSEL in one of the steps shown in FIG. 6 according to an embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

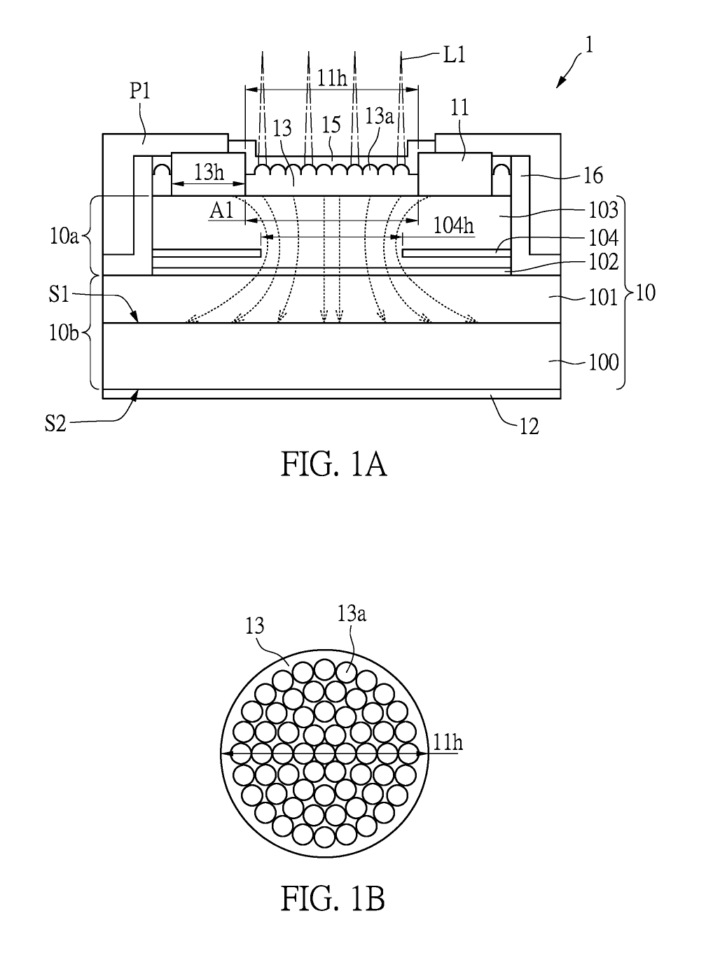

Reference is made to FIG. 1A. A vertical cavity surface emitting laser (VCSEL) 1 includes an epitaxial laminate 10, a lower electrode layer 12, an upper electrode layer 11 and a current spreading layer 13. The lower electrode layer 12, the upper electrode layer 11, and the current spreading layer 13 are disposed on the epitaxial laminate 10.

Specifically, the epitaxial laminate 10 includes a substrate 100, a first reflector 101, an active layer 102, and a second reflector 103. The first reflector 101, the active layer 102, and the second reflector 103 are disposed on the substrate 100, and the active layer 102 is interposed between the first and second reflectors 101, 103.

The substrate 100 can be a doped III-V semiconductor substrate, for example, an n-type gallium arsenide (GaAs) substrate, an n-type indium phosphide (InP) substrate, an aluminum nitride (AlN) substrate, or an indium nitride (InN) substrate. Furthermore, the substrate 100 has a top surface S1 and a bottom surface S2 opposite to the top surface S1. The first reflector 101, the active layer 102, and the second reflector 103 are sequentially disposed on the top surface S1 of the substrate 100.

Each of the first and second reflectors 101, 103 can be a distributed Bragg reflector (DBR) that is formed by alternately stacking layers having different refractive indices on top of one another, so as to allow light having a predetermined wavelength to emit out of the second reflector 103.

Each of the first reflector 101 and the second reflector 103 can include a plurality of layer pairs stacked on one another, each layer pair including two layers respectively with a high refractive index and a low refractive index. In one embodiment, the first reflector 101 is an n-type DBR, and the second reflector 103 is a p-type DBR.

As shown in FIG. 1A, the active layer 102 is formed on the first reflector 101 and includes a plurality of layers, such as a plurality of un-doped gallium arsenide layers and a plurality of un-doped aluminum gallium arsenide (Al_{y}Ga_{(1-y)}As) layers which are alternately stacked on top of one another, for forming a multi-quantum well (MQW) structure. The active layer 102 is interposed between the first reflector 101 and the second reflector 103, and excited by electric power so as to produce an initial laser beam. The initial laser beam produced by the active layer 102 is resonantly reflected between the first reflector 101 and the second reflector 103 to be amplified, and then emits out of the second reflector 103.

Furthermore, the structure of the epitaxial laminate 10 includes a base portion 10b and a mesa portion 10a disposed on the base portion 10b. The base portion 10b includes at least the substrate 100 and the first reflector 101, and the mesa portion 10b includes at least the active layer 102 and the second reflector 103.

In the embodiment, the epitaxial laminate 10 further includes a current confinement layer 104. The current confinement layer 104 is located in the second reflector 103 and has a confinement aperture 104h. Accordingly, a distribution region of the current injected into the epitaxial laminate 10 can be confined by the current confinement layer 104, so that the current only flows through the confinement aperture 104h and then into the active layer 102, thereby increasing the current density. In the instant embodiment, the current confinement layer 104 is an oxide layer. In another embodiment, the current confinement layer 104 can be a hydrogen ion implanted region that is formed in the second reflector 103 by performing a high energy hydrogen ion implantation.

Referring to FIG. 1A, both of the upper electrode layer 11 and the lower electrode layer 12 are disposed on the epitaxial laminate 10, and a current path passing through the active layer 102 is defined between the upper electrode layer 11 and the lower electrode layer 12.

In the embodiment, the upper electrode layer 11 and the lower electrode layer 12 are respectively located at two opposite sides of the substrate 100. To be more specific, the upper electrode layer 11 is positioned on the second reflector 103, and the lower electrode layer 11 is positioned on the bottom surface S2 of the substrate 100. That is to say, the upper electrode layer 11 is positioned at the mesa portion 10a, and the lower electrode layer 12 is positioned at the base portion 10b.

However, in another embodiment, the lower electrode layer 12 and the upper electrode layer 11 can be located at the same side of the substrate 100, and both of the lower electrode layer 12 and the mesa portion 10a can be disposed on the upper surface of the base portion 10b. In the present embodiment, the lower electrode layer 12 surrounds the mesa portion 10a and is disposed on the top surface of the first reflector 101. Accordingly, as long as a current that flows through the active layer 102 can be generated between the upper electrode layer 11 and the lower electrode layer 12 by applying a bias, the positions of the upper electrode layer 11 and the lower electrode layer 12 are not limited to the examples provided herein. Each of the upper electrode layer 11 and the lower electrode layer 12 can be a metal layer, an alloy layer, or a stacked layer made of different metal materials.

In the embodiment shown in FIG. 1A, the upper electrode layer 11 has an aperture 11h for defining a light-emitting region A1, and the aperture is in alignment with the confinement aperture 104h of the current confinement layer 104 so as to allow the initial laser beam produced by the active layer 102 to emit from the aperture 11h. In one embodiment, the upper electrode layer 11 is formed in the shape of a loop.

Referring to FIG. 1A, the current spreading layer 13 is disposed on the second reflector 103 and electrically connected to the upper electrode layer 11. In one embodiment, the current spreading layer 13 is made of conductive material so that the current injected from the second reflector 103 into the active layer 103 is uniformly distributed. Furthermore, the material of the current spreading layer 13 is transparent to the initial laser beam to avoid sacrificing the light efficiency of the vertical cavity surface emitting laser 1. For example, when the initial laser beam has a wavelength of 850 nm, the current spreading layer 13 can be made of doped semiconductor, such as heavily-doped gallium arsenide.

Reference is made to FIG. 1A in conjunction with FIG. 1B. In the embodiment of the present disclosure, the current spreading layer 13 includes a plurality of light-splitting structures 13a, so that the initial laser beam emitting from the second reflector 103 can be divided into a plurality of sub beams L1 through the light-splitting structures 13a. That is to say, when the sub beams L1 generated by the vertical cavity surface emitting laser 1 of the embodiment in the present disclosure are projected on an object, a plurality of light spots are formed on the surface of the object.

In the instant embodiment, the light-splitting structures 13a are located at a light emergent side of the current spreading layer 13 and include a plurality of micro-lenses. That is to say, each of the light-splitting structure can be a converging micro lens or a diverging micro lens. As shown in FIG. 1A, in the instant embodiment, each of the light-splitting structures 13a is a converging micro lens so that each of the sub beams L1 emitting out of the VCSEL 1 can be condensed, thereby increasing a projection distance of each of the sub beams L1. Furthermore, as shown in FIG. 1B, the edges of the light-splitting structures 13a (i.e., the converging micro lenses) are connected to one another.

Furthermore, at least some of the light-splitting structures 13a are located in the aperture 11h of the upper electrode layer 11. That is to say, at least some of the light-splitting structures 13a are surrounded by the upper electrode layer 11, and located in the light-emitting region A1. Accordingly, the initial laser beam can be divided into the sub beams L1 after passing through the light-splitting structures 13a.

When the VCSEL 1 in the embodiment of the present disclosure is applied in a 2D array module of an optical sensing apparatus, such as a three-dimensional camera or a time-of-flight camera, so as to capture a 3D contour of the object, the light spots projected on the surface of the object and generated by the VCSEL 1 may be several times the number of the light spots generated by the conventional VCSEL, in which the number of the light spots is dependent on the number of the light-splitting structures 13a of the VCSEL 1. In this way, the resolution and the detection accuracy of the optical sensing apparatus can be improved. When the VCSEL 1 is applied in the optical sensing apparatus, the dimension and the number of the light-splitting structures 13a can be determined according to the desired intensity of the sub beams L1. Accordingly, as long as the detecting and sensing functions of the optical sensing apparatus are not inhibited, the dimension and number of the light-splitting structures 13a are not limited in the present disclosure.

Furthermore, it should be noted that in the embodiment shown in FIG. 1B, the dimensions of the light-splitting structures 13a are substantially the same. In another embodiment, the dimensions of the light-splitting structures 13a which are located at different positions can be varied according to practical requirements. Accordingly, it is not necessary for the light-splitting structures 13a to have the same dimension in the present disclosure.

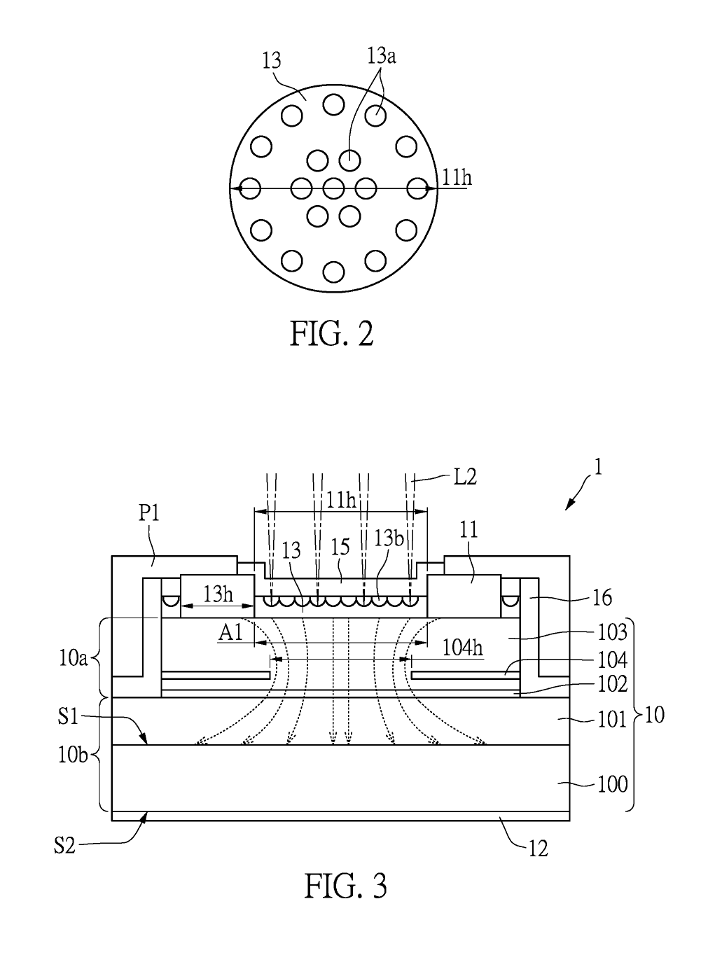

Reference is made to FIG. 2. The number of the light-splitting structures 13a is less than that in the embodiment shown in FIG. 1B, and the light-splitting structures 13a are spread out across the aperture 11.

From a top view, the light-splitting structures 13a of the instant embodiment are arranged in a concentric ring pattern. It should be noted that the light-splitting structures 13a of the current spreading layer 13 in the embodiment of the present disclosure are used to adjust the light pattern generated by the VCSEL 1 so as to increase the number of light spots for sensing, rather than functioning as a grating for generating diffraction or changing the phase of a light wave. Accordingly, in the instant embodiment, it is not necessary for the light-splitting structures 13a to have the same space therebetween. Furthermore, the light-splitting structures 13a can be asymmetrically or irregularly arranged.

In the instant embodiment, some of the light-splitting structures 13a, for example, the light-splitting structures 13a located at the center and at the innermost ring surrounding the center, can be arranged at a central region of the aperture 11h, and the other light-splitting structures 13a, which are located at the outermost ring, can be arranged at a periphery of the aperture 11h. The distribution density and the number of the light-splitting structures 13a arranged at the central region of the aperture 11h may not be the same as that of the light-splitting structures 13a arranged at the periphery of the aperture 11h.

For instance, in the embodiment shown in FIG. 2, the number of the light-splitting structures 13a arranged at the central region of the aperture 11h is less than that of the light-splitting structures 13a arranged at the periphery of the aperture 11h, while the distribution density of the light-splitting structures 13a arranged at the central region of the aperture 11h is greater than that of the light-splitting structures 13a arranged at the periphery of the aperture 11h. In other words, a space between two adjacent light-splitting structures 13a arranged at the central region of the aperture 11h is greater than that between two adjacent light-splitting structures 13a arranged at the periphery of the aperture 11h. Accordingly, after passing through the current spreading layer 13, the initial laser beam may be divided into a plurality of first sub beams with higher density at the central region and a plurality of second sub beams with lower density at the periphery.

Reference is made to FIG. 3. The light-splitting structures 13b of the instant embodiment are diverging micro lenses. That is to say, the light-splitting structures 13b of the instant embodiment of the instant embodiment are the concave portions depressed from the surface of the current spreading layer 13. When the light-splitting structures 13b are diverging micro lenses, the sub beams L2 are diverged so as to increase a projection region.

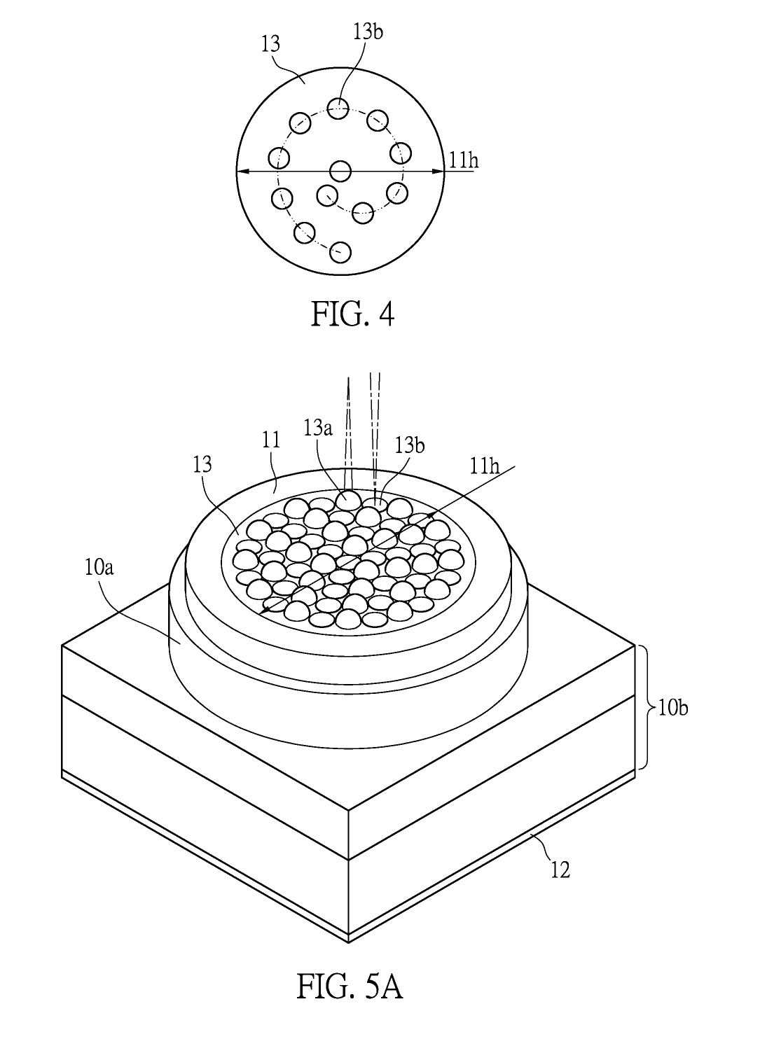

Reference is made to FIG. 4. When the light-splitting structures 13b are diverging micro lenses, the light-splitting structures 13b can also be spread out across the aperture 11. In the embodiment shown in FIG. 4, the light-splitting structures 13b can be arranged to be in a spiral pattern from a top view according to a desired light pattern of the sub beams, but the present disclosure is not limited to the example provided herein.

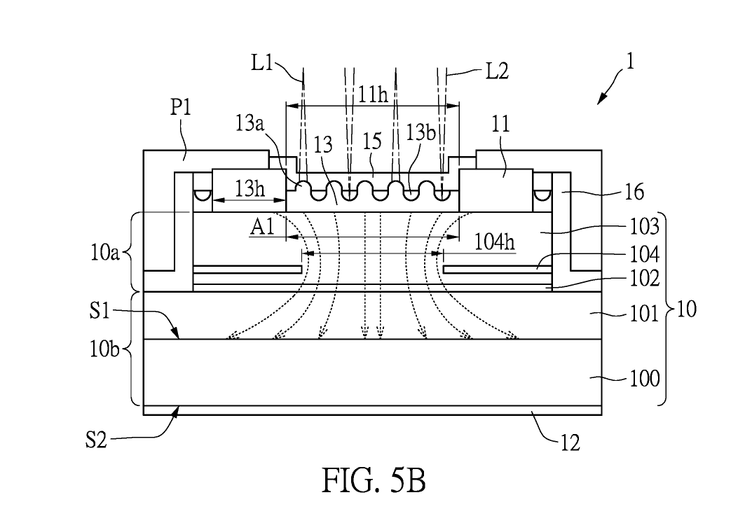

Reference is made to FIG. 5A and FIG. 5B. In the instant embodiment, the light-splitting structures 13a, 13b include a plurality of converging micro lenses and diverging micro lenses. The converging micro lenses can be scattered among the diverging micro lenses. Specifically, the converging micro lenses and the diverging micro lenses can be arranged in concentric circles, and the converging micro lenses and the diverging micro lenses of each circle can be alternately arranged.

As shown in FIG. 5B, the diverging micro lenses are concave portions depressed from the surface of the light spreading layer 13, and the converging micro lenses are convex portions protruding from the surface of the light spreading layer 13. In the instant embodiment, the concave portion of the diverging micro lens and the convex portion of the converging micro lens are both curved surfaces. Accordingly, a portion of the initial laser beam generated by the active layer 102 passing through the diverging micro lenses is divided into a plurality of sub beams L2, and each of the sub beams L2, which are respectively diverged by the diverging micro lenses, has a larger projection region. Another portion of the initial laser beam passing through the converging micro lenses is divided into a plurality sub beams L1, and each of the sub beams L1, which are respectively converged by the converging micro lenses, has a greater projection distance.

In the instant embodiment, the light-splitting structures 13a, 13b include the converging and diverging micro lenses, such that the beams emitting from the VCSEL 1′ in the embodiment of the present disclosure have greater projection distances or larger projection regions.

Furthermore, the arrangement of the converging and diverging micro lenses illustrated in FIG. 5A is exemplary only and does not limit the scope of the present disclosure. The arrangement of the converging and diverging micro lenses can be varied according to practical requirements so as to optimize the projection regions, the projection distances, and the intensities of the sub beams emitting from different regions.

Reference is made to FIG. 1A. In one embodiment, the current spreading layer 13 further has an opening pattern 13h. In the instant embodiment, the upper electrode layer 11 partially covers the current spreading layer 13, and a portion of the upper electrode layer 11 fills into the opening pattern 13h so as to be in contact with the second reflector 103. The opening pattern 13h from a top view is in the shape of a loop, and the opening pattern 13h surrounds the light-splitting structures 13a. In another embodiment, the opening pattern 13h may be omitted from the current spreading layer 13, and the upper electrode layer 11 may be directly disposed on the current spreading layer 13.

Furthermore, in the instant embodiment, the VCSEL 1 further includes a top protection layer 15 and a sidewall protection layer 16. The top protection layer 15 and the sidewall protection layer 16 are made of an insulating material, such as silicon nitride.

The top protection layer 15 covers the upper electrode layer 11 and the current spreading layer 13. In the instant embodiment, the top protection layer 15 covers the light emitting region A1. Accordingly, the material of the top protection layer 15 can be selected from materials that are transparent to the sub beams L1 (or L2).

Additionally, the sidewall protection layer 16 partially covers the sidewall surfaces of the epitaxial laminate 10. To be more specific, the sidewall protection layer 16 covers a sidewall of the mesa portion 10a and an upper surface of the base portion 10b.

As shown in FIG. 1A, in the instant embodiment, the VCSEL 1 further includes a contact layer P1 disposed on the top protection layer 15. The contact layer P1 passes through the top protection layer 15 and is in electrical contact with the upper electrode layer 11 to serve as a wire bonding region. In the instant embodiment, the contact layer P1 covers the sidewall protection layer 16 and is insulated from the first reflector 101 by the sidewall protection layer 16.

Accordingly, in the VCSEL 1 of the embodiment in the present disclosure, the current can be uniformly injected into the active layer 102 by the inclusion of the current spreading layer 13 having the opening pattern 13h. Furthermore, the initial laser beam can be divided into the sub beams L1 (or L2) by the current spreading layer 13 which includes the light-splitting structures 13a (or 13b) located at the light emergent side thereof.

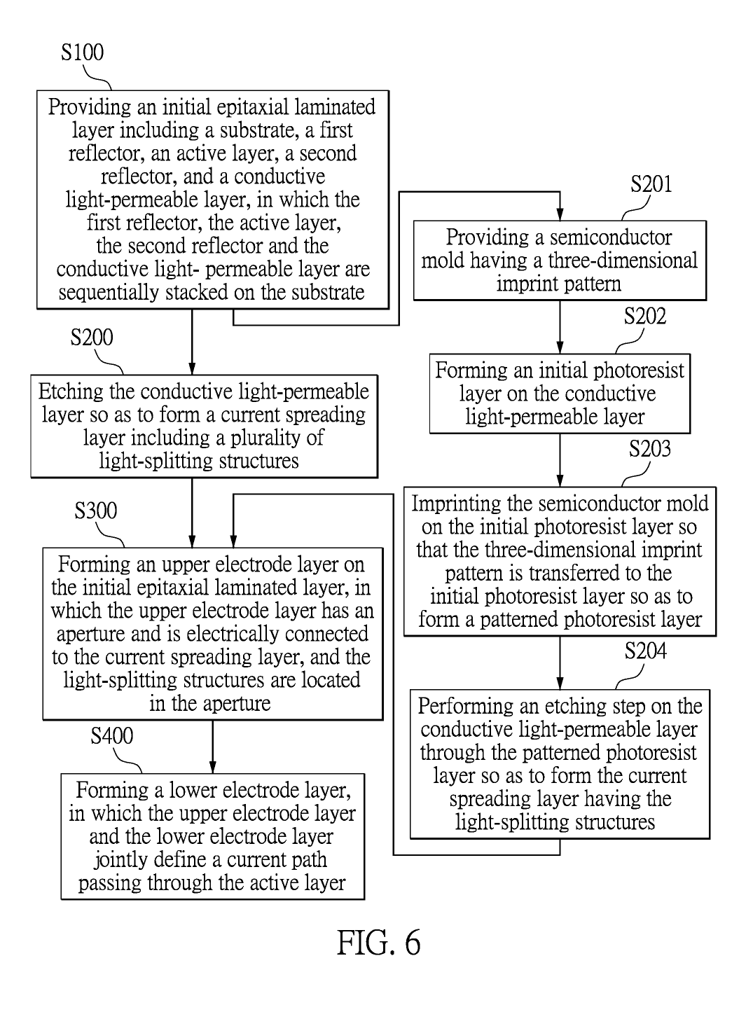

Reference is made to FIG. 6. FIG. 6 is a flowchart of a method for fabricating a VCSEL according to an embodiment of the present disclosure. In step S100, an initial epitaxial laminated layer is provided, in which the initial epitaxial laminated layer includes a substrate, a first reflector, an active layer, a second reflector and a conductive light-permeable layer. The first reflector, the active layer, the second reflector and the conductive light-permeable layer are sequentially stacked on the substrate.

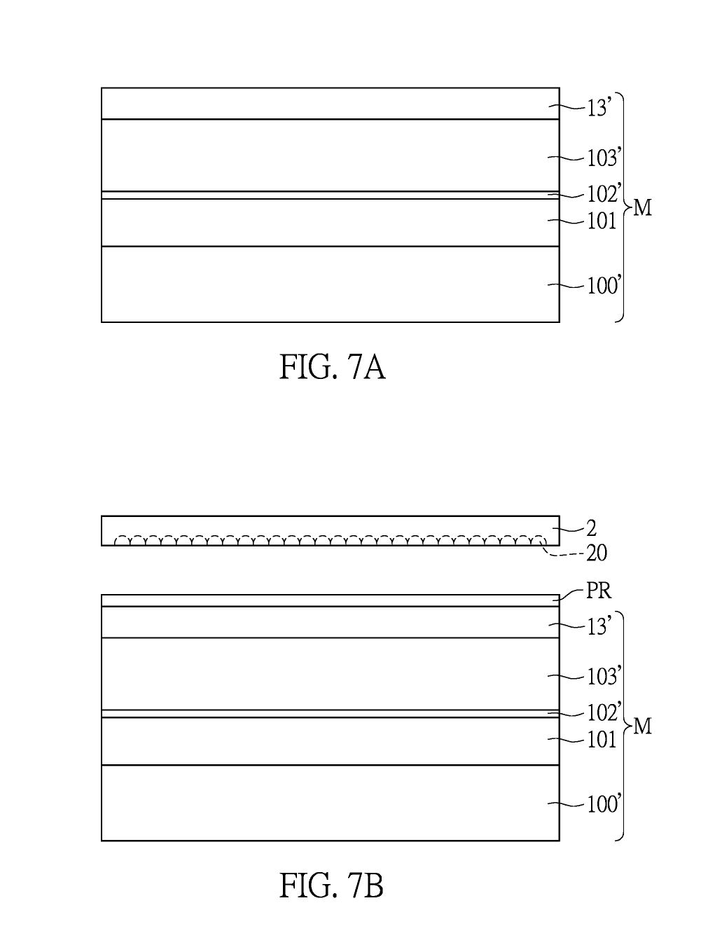

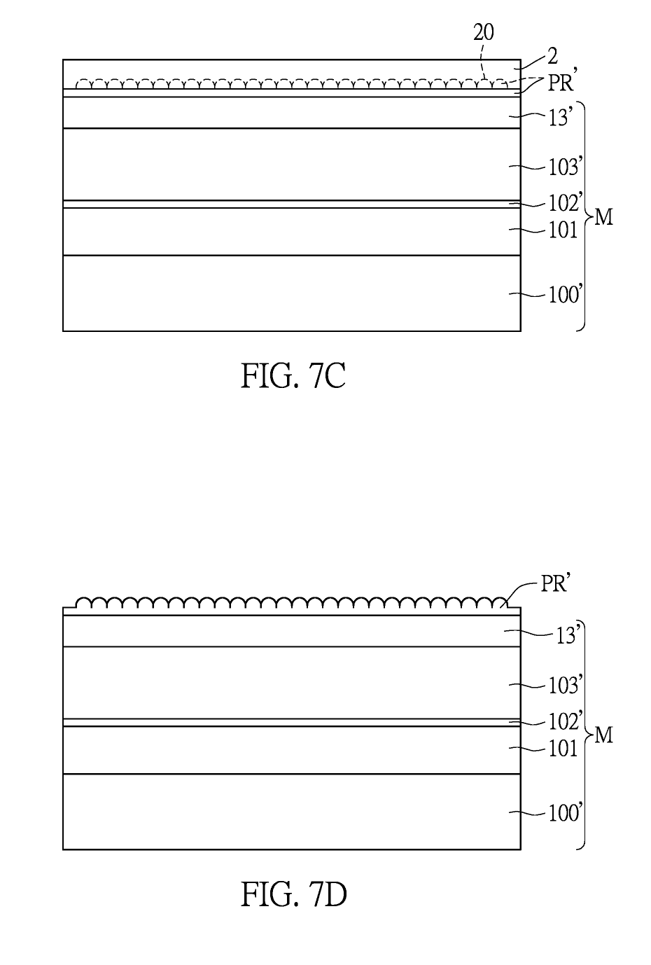

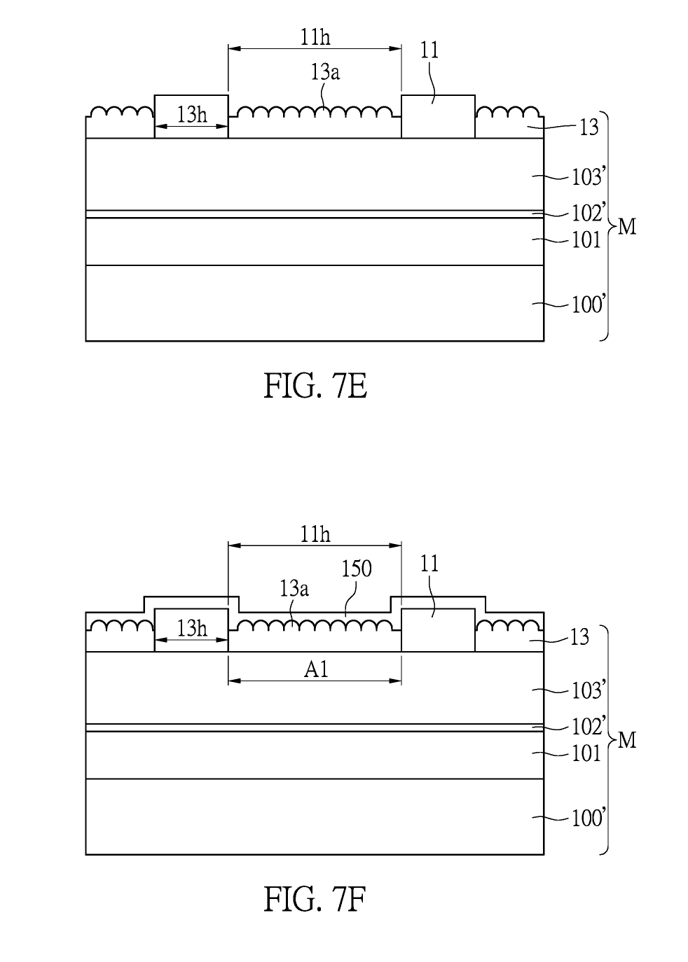

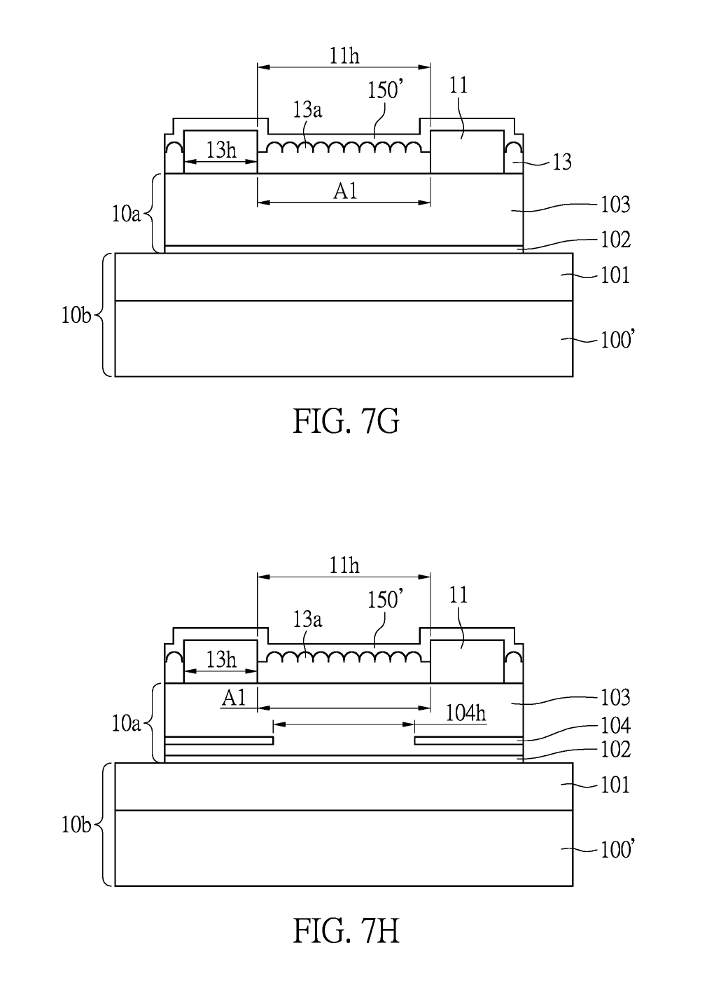

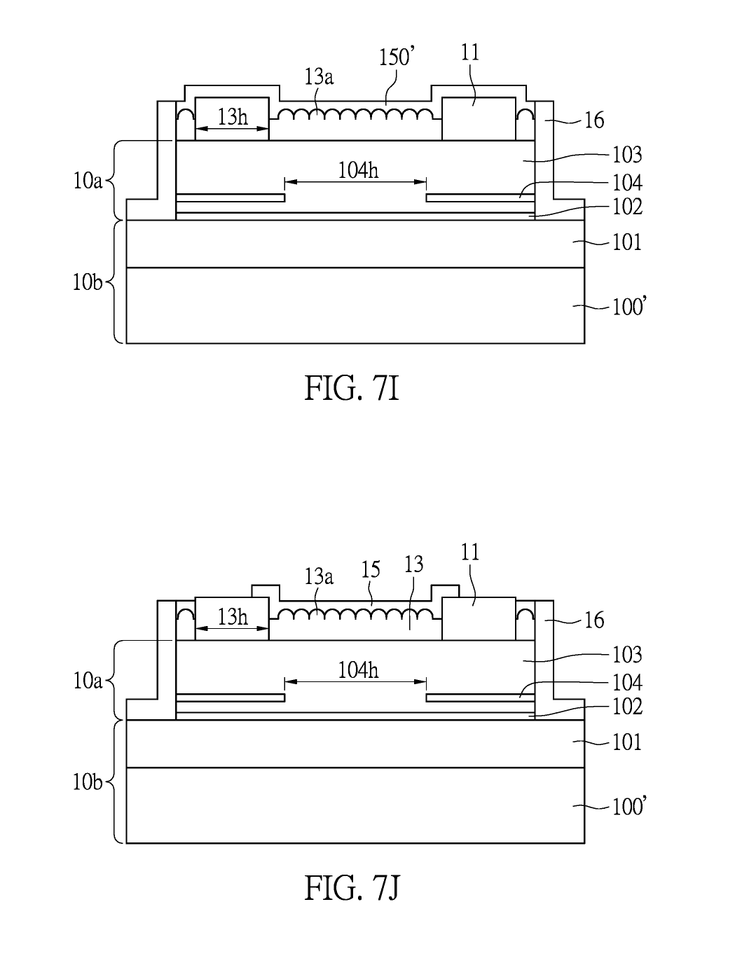

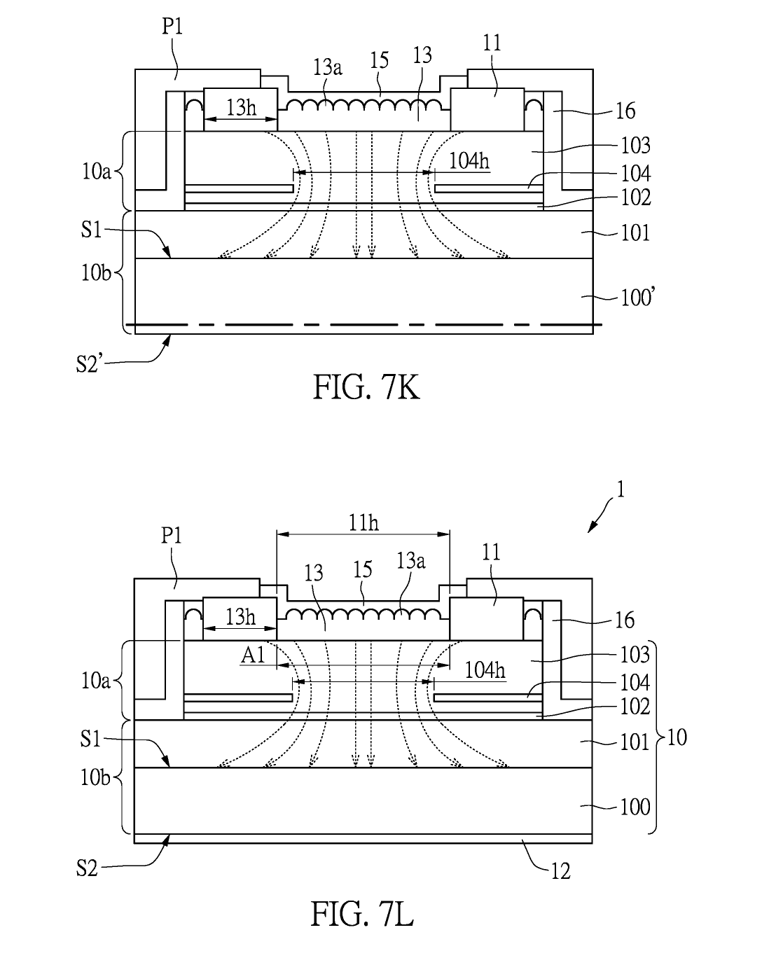

Reference is made to FIG. 7A. The initial epitaxial laminated layer M includes the substrate 100′, the first reflector 101, the active layer 102′, the second reflector 103′, and the conductive light-permeable layer 13′. In one embodiment, the aforementioned layers can be formed by performing a metal-organic chemical vapor deposition (MOCVD) process. The conductive light-permeable layer 13′ can be made of a conductive material allowing the initial light generated by the active layer 102′ to pass through, such as doped semiconductor materials or conductive transparent materials. For example, when the initial laser beam is a visible beam, the material of the conductive light-permeable layer 13′ can be indium tin oxide.

Reference is made to FIG. 6. In step S200, the conductive light-permeable layer is etched so as to form a current spreading layer including a plurality of light-splitting structures. To be more specific, the conductive light-permeable layer can be etched by performing a nanoimprint etching process to form the current spreading layer including the light-splitting structures 13a (13b). In the instant embodiment, the nanoimprint etching process can be used to form a nanoscale pattern, and thus is suitable for fabrication of the light-splitting structures 13a (13b) of the current spreading layer 13 in the present disclosure.

In one embodiment, details of patterning the conductive light-permeable layer 13′ can be referred to in the steps S201-S204 shown in FIG. 6 in conjunction with FIG. 7B to FIG. 7E.

Specifically, in step S201, a semiconductor mold having a three-dimensional imprint pattern is provided. As shown in FIG. 7B, the semiconductor mold 2 has the three-dimensional imprint pattern 20. It should be noted that in the instant embodiment, the three-dimensional imprint pattern 20 is a nanoscale pattern which can be fabricated by an electron beam lithography technique. It should be noted that in FIG. 7B, the three-dimensional imprint pattern 20 shown in FIG. 7B is designed for the exemplified fabrication of the VCSEL 1 shown in FIG. 1A. In other embodiments, the design of the three-dimensional imprint pattern 20 can also be varied according to the shapes of the light-splitting structures to be fabricated.

Reference is made to FIG. 6. In step S202, an initial photoresist layer is formed on the conductive light-permeable layer. It should be noted that the steps S201 and S202 can be performed in an exchanged sequence or performed simultaneously. In step S203, the semiconductor mold is imprinted on the initial photoresist layer so that the three-dimensional imprint pattern is transferred to the initial photoresist layer so as to form a patterned photoresist layer.

As shown in FIG. 7B, the initial photoresist layer PR is formed on the conductive light-permeable layer 13′. As shown in FIG. 7C, the three-dimensional imprint pattern 20 of the semiconductor mold 2 is imprinted into the initial photoresist layer PR, so that the three-dimensional imprint pattern 20 is transferred to the initial photoresist layer PR, and a patterned photoresist layer PR′ having a transferred pattern is then formed. It should be noted that in one embodiment, after the semiconductor mold 2 is pressed on the initial photoresist layer PR, a photoresist residue may still remain in a pressed portion of the initial photoresist layer PR. Accordingly, the photoresist residue remaining in the pressed portion can be removed before the next step is performed.

In another embodiment, the three-dimensional imprint pattern 20 of the semiconductor mold 2 can be filled with a photoresist material. Thereafter, the photoresist material can be transferred to the surface of the conductive light-permeable layer 13′.

Reference is made to FIG. 6. The method proceeds to step S204, in which an etching step is performed on the conductive light-permeable layer through the patterned photoresist layer so as to form the current spreading layer including the light-splitting structure and an opening pattern.

Reference is made to FIG. 7E. After the conductive light-permeable layer 13′ is etched through the patterned photoresist layer PR′, the current spreading layer 13 having a plurality of light-splitting structures 13a is formed, the light-splitting structures 13a being located at the light emergent side of the current spreading layer 13. Since the scale of each of the light-splitting structures 13a is very small, the light-splitting structure 13a can be formed by performing the nanoimprint etching process in the present disclosure. Compared to the other conventional etching processes, the shape and size of each of the light-splitting structures 13a can be precisely controlled by using the nanoimprint etching process.

In the instant embodiment, after the light-splitting structures 13a are formed, the method further includes a step of forming the opening pattern 13h in the current spreading layer 13. Furthermore, before the next step is performed, the patterned photoresist layer PR′ can be removed. Reference is made to FIG. 6 and FIG. 7E. In step S300, an upper electrode layer 11 is formed on the initial epitaxial laminated layer M. The upper electrode layer 11 is electrically connected to the current spreading layer 13 and has an aperture 11h for defining a light-emitting region A1. To be more specific, the upper electrode layer 11 can be directly formed on the current spreading layer 13, and a portion of the upper electrode layer 11 fills into the opening pattern 13h.

Furthermore, the top view of the upper electrode layer 11 is formed in the shape of a loop. Accordingly, the upper electrode layer 11 surrounds the light-splitting structures 13a which are located in the aperture 11h. That is to say, some of the light-splitting structures 13a of the current spreading layer 13 are located in the aperture 11h. In the embodiment of the present disclosure, the upper electrode layer 11 can be formed by performing a physical vapor deposition process, such as an evaporation process.

Reference is made to FIG. 7F. After the upper electrode layer 11 is formed, the method for fabricating the VCSEL can further include a step of forming a protection material layer 150 covering the upper electrode layer 11 and the current spreading layer 13, as shown in FIG. 7F. The aforementioned protection material layer 150 can be a silicon nitride layer. However, the material of the protection material layer 150 can be selected according to the wavelength of the initial laser beam, and the present disclosure is not limited to the example provided herein.

Reference is made to FIG. 7G. In the instant embodiment, the method further includes a step of etching the initial epitaxial laminated layer M to form a mesa portion 10a. Specifically, the mesa portion 10a can be formed by performing a chemical etching process.

Reference is made to FIG. 7H. After the mesa portion 10a is formed, a current confinement layer 104 can be formed in the second reflector 103. In one embodiment, the current confinement layer 104 can be formed by performing a lateral oxidation process to oxidize one portion of the second reflector 103 (usually one with a high aluminum concentration). That is to say, the current confinement layer 104 is an oxide layer. Furthermore, the current confinement layer 104 has a confinement aperture 104h to allow the current to flow therethrough. The confinement aperture 104h corresponds to the light-emitting region A1 defined by the aperture 11h of the upper electrode layer 11.

Specifically, since the current confinement layer 104 formed in the second reflector 103 has a higher resistance, the current flows around the current confinement layer 104 and is only permitted to pass through the confinement aperture 104h. Accordingly, the current density of the current injected into the active layer 102 can be increased.

Reference is made to FIG. 7I. The sidewall protection layer 16 is formed to cover the sidewall of the mesa portion 10a. In the instant embodiment, the material of the sidewall protection layer 16 may not be the same as that of the protection material layer 150′. That is to say, it is not necessary to select a material allowing the initial laser beam to pass through for the sidewall protection layer 16, and the sidewall protection layer 16 may be made of the other materials.

Reference is made to FIG. 7J and FIG. 7K. The contact layer P1 is formed to be electrically connected to the upper electrode layer 11. As shown in FIG. 7J and FIG. 7K, after an opening is formed in the protection material layer 150′, a conductive material can be formed to serve as the contact layer P1. The conductive material fills into the opening such that the contact layer P1 can be electrically connected to the upper electrode layer 11.

Reference is made to FIG. 6 in conjunction with FIG. 7K and FIG. 7L. In step S400, a lower electrode layer 12 is formed, in which the upper electrode layer 11 and the lower electrode layer 12 jointly define a current path that passes through the active layer 102. It should be noted that before the lower electrode layer 12 is formed, the substrate 100′ can be grinded from the back side thereof so as to thin the substrate 100′, as shown in FIG. 7K. Subsequently, the lower electrode layer 12 can be formed on a bottom surface S2 of the substrate 100 that has been thinned, as shown in FIG. 7L. However, in another embodiment, the step of forming the lower electrode layer 12 on the upper surface of the base portion 10b can be followed by the steps of forming the sidewall protection layer 16 and the contact layer P1.

In conclusion, one of the advantages of the present disclosure is that in the VCSEL and the method for fabricating the same, by “disposing the current spreading current 13 having the light-splitting structures 13a (13b) on the second reflector 103,” the current injected into the active layer 102 can be more uniformly distributed. Furthermore, the initial laser beam generated by the active layer 102 can be divided into a plurality of sub beams L1 (L2) emitting out of the VCSEL by passing through the light-splitting structures 13a (13b).

Accordingly, when the VCSEL 1 of the embodiment in the present disclosure is applied in the two-dimensional array of the optical sensing apparatus to capture a 3D contour of an object, the number of the light spots projected on the object can be increased without increasing the number of the VCSEL, thereby improving the resolution and the detection accuracy.

Furthermore, in the method for fabricating a VCSEL in the embodiment of the present disclosure, the current spreading layer 13 having the light-splitting structures 13a (13b) can be formed by performing the nanoimprint etching process.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A vertical cavity surface emitting laser comprising:
an epitaxial laminate including a substrate, a first reflector, an active layer, and a second reflector, wherein the first reflector, the active layer and the second reflector are disposed on the substrate, and the active layer is interposed between the first and second reflectors to generate an initial laser beam;
a lower electrode layer disposed on the epitaxial laminate;
an upper electrode layer disposed on the second reflector, wherein the upper electrode layer and the lower electrode layer jointly define a current path therebetween passing through the active layer, and the upper electrode layer has an aperture for defining a light-emitting region; and
a current spreading layer disposed on the second reflector and electrically connected to the lower electrode layer, wherein the current spreading layer includes a plurality of light-splitting structures located at a light emergent side of the current spreading layer, and the light-splitting structures are located in the aperture so that the initial laser beam passing through the light-splitting structures is divided into a plurality of sub beams.

2. The vertical cavity surface emitting laser according to claim 1, wherein each of the light-splitting structure is a converging micro lens or a diverging micro lens.

3. The vertical cavity surface emitting laser according to claim 1, wherein the light-splitting structures include a plurality of converging micro lenses and a plurality of diverging micro lenses, and the converging micro lenses are scattered among the diverging micro lenses.

4. The vertical cavity surface emitting laser according to claim 1, wherein the light-splitting structures are spread out across the light-emitting region.

5. The vertical cavity surface emitting laser according to claim 1, wherein the edges of the light-splitting structures are connected to one another.

6. The vertical cavity surface emitting laser according to claim 1, wherein the current spreading layer is made of a doped semiconductor material.

7. The vertical cavity surface emitting laser according to claim 1, wherein the current spreading layer has an opening pattern, and a portion of the upper electrode layer fills into the opening pattern so as to be in contact with the second reflector.

8. A method for fabricating a vertical cavity surface emitting laser comprising:
providing an initial epitaxial laminated layer including a substrate, a first reflector, an active layer, a second reflector and a conductive light-permeable layer, wherein the first reflector, the active layer, the second reflector and the conductive light-permeable layer are sequentially stacked on the substrate;
etching the conductive light-permeable layer to form a current spreading layer having a plurality of light-splitting structures, wherein the light-splitting structures are located at a light emergent side of the current spreading layer;
forming an upper electrode layer on the initial epitaxial laminated layer, wherein the upper electrode layer has an aperture for defining a light-emitting region, the upper electrode layer is electrically connected to the current spreading layer, and the upper electrode layer surrounds the light-splitting structures; and
forming a lower electrode layer, wherein the upper electrode layer and the lower electrode layer jointly define a current path therebetween that passes through the active layer.

9. The method for fabricating the vertical cavity surface emitting laser according to claim 8, wherein the current spreading layer having the light-splitting structures is formed by performing a nanoimprint etching process on the conductive light-permeable layer.

10. The method for fabricating the vertical cavity surface emitting laser according to claim 8, wherein the step of etching the conductive light-permeable layer further comprising:
providing a semiconductor mold including a three-dimensional imprint pattern;
forming an initial photoresist layer on the conductive light-permeable layer;
imprinting the semiconductor mold on the initial photoresist layer so that the three-dimensional imprint pattern is transferred to the initial photoresist layer so as to form a patterned photoresist layer; and
performing an etching process on the conductive light-permeable layer through the patterned photoresist layer so as to form the current spreading layer having the light-splitting structures.
